(19) United States
(12) Patent Application Publication
(10) Pub. No.: US 2004/0227186 A1
(43) Pub. Date: Nov. 18, 2004

(54) Semiconductor device

(76) Inventors: Shinichi Saito, Kawasaki (JP); Digh Hisamoto, Kokubunji (JP); Kazuyoshi Torii, Tsukuba (JP); Yasuhiro Shimamoto, Leuven (JP)

Correspondence Address: REED SMITH LLP, Suite 1400, 3110 Fairview Park Drive, Falls Church, VA, 22042, US

(21) Appl. No.: 10/765,198

(22) Filed: Jan. 28, 2004

(30) Foreign Application Priority Data
Feb. 10, 2003 (JP) P2003-032529

(51) Int. Cl. H01L 27/01

(52) U.S. Cl. 257/347

(57) ABSTRACT

Disclosed are a semiconductor device which hardly experiences a reduction in mobility caused by scattering by the fixed charge existent in a gate insulating film while the EOT of a fine CMOS comprising the high-dielectric gate insulating film is reduced and which enables high integration, and a production process therefor. CMOS having no junction is formed on an SOI substrate and a high-dielectric gate insulating film is used as the gate insulating film of the CMOS. The feature of the CMOS device of the present invention is that the CMOS device is operated in an accumulation mode. Since a channel is formed several nm away from the surface of the substrate as compared with an ordinary device which operates in an inversion mode, a reduction in mobility caused by the fixed charge existent in the gate insulating film can be reduced.

### PRIORITY CLAIM

This application claims priority under 35 USC §119 to Japanese patent application P-2003-032529 filed Feb. 10, 2003, the entire disclosure of which is hereby incorporated herein by reference.

### FIELD OF THE INVENTION

The present invention relates to a semiconductor device and to a production process therefore and, more specifically, to a semiconductor device having a high-dielectric gate insulating film on a SOI substrate and to a production process therefore.

### BACKGROUND OF THE INVENTION

Integrated circuit technology using silicon has been developing at a remarkable speed. Along with progress in lithography, the size of each device has been reduced, thereby making it possible to integrate more devices on one chip and to realize more functions. At the same time, processing speed has been increased by the improvement of current drive ability and the reduction of load capacity due to a reduction in the size of each device. The mainstream of the current silicon device market is a CMOS (Complementary Metal Oxide Semiconductor Field Effect Transistor) and a CMOS product having a channel length of less than 0.1 μm has already been available on the market.

A CMOS device having a very small channel length has a problem such as the occurrence of a phenomenon called “punch-through” wherein a current runs between a source diffusion layer and a drain diffusion layer because they are close to each other, thereby interconnecting a depletion layer on the source side and a depletion layer on the drain side, though no channel is formed therebetween. Therefore, the characteristic properties of the device are deteriorated by what is called “short channel effect”, as exemplified by the reduction of threshold voltage and the deterioration of sub-threshold characteristics. To prevent this short channel effect, there is known a method for increasing the impurity concentration of a channel portion by ion injection. When this method is used, a larger amount of an impurity must be added as a transistor is made smaller in size. In fact, the impurity concentration of the substrate of the currently most advanced transistor reaches 1×10¹⁸(cm⁻³). However, when the impurity concentration becomes so high, channel carriers are scattered by the scattering of an impurity, thereby reducing mobility.

To cope with this, the next-generation CMOS formed on a SOI (Silicon On Insulator) substrate which is hardly affected by the short channel effect without increasing the concentration of an impurity is expected to become the main stream of the market. The SOI substrate is a substrate having a structure wherein a silicon monocrystalline layer (SOI layer) is formed on the surface of a silicon monocrystalline substrate through a silicon dioxide layer (buried oxide layer or BOX layer). A device formed on the SOI substrate is called a “SOI device” and a device formed on a bulk silicon substrate is called “bulk device” so that they can be distinguished from each other. Since the SOI device has a BOX layer, when no channel is formed, a current hardly runs between the source diffusion layer and the drain diffusion layer. Therefore, the SOI device can show better short channel characteristics while it maintains the low impurity concentration of the channel portion. Consequently, the SOI device can show high current drive ability without causing a reduction in mobility due to the scattering of the impurity caused by an increase in its concentration. The SOI device can reduce parasitic capacity, has excellent radiation resistance and is therefore expected to have higher performance and higher reliability than the bulk device. The excellent features of the SOI device are disclosed in the non-patented Document 1, D. Hisamoto, “IEEE Electron Devices Meeting, 2001, IEDM Technical Digest International”, 2001, p. 19.3.1-19.3.4 for example.

Efforts have been made to reduce the pattern width of a device in order to improve current drive ability, and efforts to reduce the thickness of a gate insulating film are the most typical example thereof. A device product comprising a gate insulating film having a thickness of less than 2 nm has already been available on the market. In the research field, the non-patented Document 2, R. Chau, “IEEE Electron Devices Meeting, 2000, IEDM Technical Digest International”, 2000, p.45, reports the operation of a CMOS device comprising a gate insulating film having a thickness of 0.8 nm. The thickness of this gate insulating film is equivalent to the total thickness of three silicon dioxide atomic layers used as a gate insulating film.

However, if a very thin oxide film having a thickness of less than 2 nm is used as the gate insulating film, various problems will occur. The most serious problem out of them is a leak current running through the gate insulating film caused by a direct tunnel effect. The direct tunnel effect becomes marked when the thickness of the gate insulating film becomes smaller than about 4 nm. Even a device product has already reached a level that the leak current becomes apparent. The leak current is multiplied by an exponential function as the gate insulating film becomes thinner. Therefore, when the gate insulating film is made thin, the power consumption is multiplied by an exponential function. For example, the non-patented Document 3, P. P. Gelsinger, “Solid-State Circuits Conference, 2001, Digest of Technical Papers, ISSCC, 2001 IEEE International”, 2001, p.22-25 estimates simply from the current technical trend that the power consumption of a chip per unit area will increase to a value equivalent to the caloric value of an atomic power plant in 2005. Therefore, the reduction of the thickness of a silicon dioxide gate insulating film is obviously reaching its limit.

In order to further proceed with the reduction of the pattern width of CMOS beyond the limit in the reduction of the thickness of a silicon dioxide gate insulating film, the energetic research and development of a high-dielectric gate insulating film in place of a silicon dioxide gate insulating film are now under way worldwide. The high-dielectric gate insulating film is a gate insulating film made from a material having a higher dielectric constant than silicon dioxide, such as a silicon oxy nitride film, silicon nitride film, Al₂O₃ film, HfO₂ film, ZrO₂ film or laminate film thereof. When the high-electric gate insulating film is used, the physical thickness of a gate insulating film can be made larger than when silicon dioxide is used. That is, when the dielectric constant of the high-dielectric gate insulating film is represented by ∈_{high-k}, the dielectric constant of silicon dioxide is represented by ∈_{SiO2}, and the physical thickness of the high-dielectric gate insulating film is represented by ∈_{phys}, the thickness tₒₓ of the high-dielectric gate insulating film in terms of a silicon dioxide film (equivalent oxide thickness, often abbreviated as EOT) is obtained from the equation tₒₓ=t_{phys}·∈_{high-k}/∈_{SiO2}. Accordingly, when the thickness of a silicon dioxide gate insulating film is equal to the equivalent oxide thickness of the high-dielectric gate insulating film, the physical thickness of the high-dielectric gate insulating film is larger than the silicon dioxide gate insulating film. Therefore, a leak current can be reduced by the direct tunnel effect. Consequently, when a high-dielectric gate insulating film is used, a drive current can be increased and a leak current can be reduced while the physical thickness of the gate insulating film can be kept large by reducing the oxide equivalent thickness of the high-dielectric gate insulating film. Consequently, the high-dielectric gate insulating film is greatly expected as the next-generation gate insulating film.

However, when a high-dielectric gate insulating- film is used, mobility greatly lowers as compared with when silicon dioxide is used. For example, the non-patented Document 4, D. A. Buchanan et al., “IEEE Electron Devices Meeting, IEDM Technical Digest International”, 2000, p.223 discloses that when an Al₂O₃ film is used as a gate insulating film, mobility does not reach 100 cm²/Vs at best. The reason for this is that it is most likely that the carriers of a channel are scattered by the fixed charge existent in the high-dielectric gate insulating film. This scattering is called “remote charge scattering”. The reason why it is called “remote” is that fixed charge which is a scattering body is away from the channel. Therefore, the carriers do not collide with the fixed charge directly but the courses of the carriers are curved by a potential generated by the fixed charge, thereby reducing mobility.

The reasons why this remote charge scattering occurs when the high-dielectric gate insulating film is used are (i) that the number of carriers is small and a reduction in mobility on a low electric field side where charge is not fully screened is large, (ii) that mobility is not greatly improved even when lattice vibration is suppressed by reducing temperature, and (iii) that flat band voltage changes according to capacity-voltage characteristics and fixed charge is existent in the gate insulating film. Since mobility is directly connected with a drive current, to activate a device at a high speed, mobility must be increased. It is known that when a conventional silicon dioxide gate insulating film is used, mobility is not based on process conditions but on a curve called “universal curve”. To replace a silicon dioxide gate insulating film with a high-dielectric gate insulating film, mobility when the high-dielectric gate insulating film is used must be made close to this universal curve.

It is considered that the reduction of the amount of fixed charge which is the cause of reducing mobility, ideally the removal of all the fixed charge is the most effective in improving mobility. To reduce the amount of fixed charge, for example, the non-patented Document 5, K. Torii et al., “2001, Extended Abstracts of International Workshop on Gate Insulator (IWGI)”, 2001, p.230, discloses a method for improving mobility up to 200 cm²/Vs by annealing an Al₂O₃ film at a high temperature (700 to 1,000° C.) and a reduced pressure in an oxygen atmosphere in place that it is annealed at a low temperature (400 to 500° C.) and atmospheric pressure in an oxygen atmosphere after it is formed. This is made possible by reducing the amount of fixed charge.

However, even when this method is used, the improved mobility is about half of mobility obtained when a conventional silicon dioxide gate insulating film is used. It cannot be said that the mobility is improved to a value sufficiently high enough to replace the silicon dioxide gate insulating film with a high-dielectric gate insulating film. This is because there is unknown an effective method for completely removing this fixed charge with the currently most advanced technology. That is, there does not exist any decisive method for improving mobility to the same level as the universal curve by fully reducing the amount of fixed charge with the current technology for forming a high-dielectric gate insulating film.

As an alternative method for improving mobility, the patented Document 1, JP-A No. 313951/2002, discloses a method for improving electric properties such as mobility and flat-band voltage by forming an interface oxide film having a thickness of 0.5 nm or more between an Al₂O₃ film and a silicon substrate to keep fixed charge away from a channel. According to the non-patented Document 6, K. Torii et al., “Digest of Technical Papers, Symposium on VLSI Technology”, 2002, p.188-189, since fixed charge is existent at the interface between an interface oxide film and a high-dielectric gate insulating film, when the interface layer becomes thick, a coulomb potential generated by the fixed charge becomes small, thereby making it difficult for fixed charge to scatter the carriers of the channel. When this method is used, for example, the mobility of a metal insulator semiconductor field effect transistor (to be abbreviated as MISFET) produced by forming a 2.0 nm-thick interface oxide film and then a 2.0 nm-thick Al₂O₃ film on the interface oxide film is improved to the same level as a MISFET having a 2.0 nm-thick silicon dioxide gate insulating film. However, as the physical thickness of the gate insulating film becomes large with this method, it is difficult to design a device which has mobility close to the value of the universal curve while EOT of the gate insulating film is reduced.

As a further alternative method for improving mobility, the non-patented Document 7, K. Rim, et al., “Digest of Technical Papers, Symposium on VLSI Technology”, 2002, session 2-1 discloses a technology for improving mobility up to 300 cm²/Vs by forming a high-dielectric gate insulating film on strained silicon. This is the technology for achieving high mobility by changing the band structure with strained silicon. When this technology is used, mobility on a high electric field side can be made higher than that of the universal curve. However, the technology using strained silicon is not completed to a level that it can be introduced into a product as a total process. The most serious problem to be solved is that devices cannot be highly integrated because devices cannot be separated from one another by shallow trench isolation. It is also feared that a defect may occur in crystals when a SiGe layer is formed by epitaxial growth. Further, as the diffusion coefficient of an impurity differs from that of an ordinary silicon substrate, it is not verified whether a fine CMOS which suppresses a single channel effect can be formed or not.

Therefore, according to the non-patented Document 8, “International Technology Roadmap for Semiconductor (ITRS)”, Sematech, 2001 the strained silicon technology is considered as the next-generation technology to be introduced in 2007 or later at the earliest. Consequently, it cannot be said that the technology for improving the mobility of MISFET having a high-dielectric gate insulating film formed by using strained silicon is a practical and decisive solution.

In view of the above problems, the present invention may provide a semiconductor device which hardly experiences a reduction in mobility caused by scattering by the fixed charge existent in a gate insulating film while the EOT of a fine CMOS comprising the high-dielectric gate insulating film is reduced easily by the current technology and enables high integration as well as a production process therefore. It is another object of the present invention to provide a semiconductor device which is resistant to a single channel effect, has a small leak current and has high-speed CMOS devices highly integrated thereon as well as a production process therefore.

### SUMMARY OF THE INVENTION

The present invention attains a fine CMOS having a small leak current and high mobility which is produced by forming a CMOS having no junction on a SOI substrate and using a high-dielectric gate insulating film as the gate insulating film of the CMOS. The feature of the CMOS device of the present invention is that the CMOS device is operated in an accumulation mode. As a channel is formed several nm away from the surface of the substrate as compared with an ordinary device which operates in an inversion mode, a reduction in mobility caused by the fixed charge existent in the gate insulating film is small.

The CMOS device of the present invention is characterized in that the conductive type of an impurity in a channel portion is made the same as the conductive type of the source diffusion layer and that conductive type of the drain diffusion layer which are existent adjacent to the channel portion by using the SOI substrate to eliminate a PN junction from the CMOS device. Since the channel portion must be fully depleted to turn off the device, a conventional silicon wafer without the BOX layer cannot be used as a substrate, and the SOI substrate must be used. Thus, in a CMOS having no PN junction, a current is caused to run between the source and the drain by setting the CMOS in an accumulation mode to turn on the device. Therefore, this CMOS device will be referred to as “accumulation mode SOI device” hereinafter.

FIG. 2 shows comparison of mobility between an accumulation mode and an inversion mode when a conventionally silicon dioxide gate insulating film is used.

The accumulation mode and the inversion mode are defined as follows.

The accumulation mode is that when the channel portion is in an accumulation state, a transistor is turned on. In the accumulation mode, the conductive type of the channel portion and the polarity of the carriers are the same. That is, when the conductive type of the channel portion is N, the number of electrons which become carriers in the accumulation mode becomes larger than the number of holes. In contrast to this, the inversion mode is that when the channel portion is in an inversion state, the transistor is turned on.

It is known that when a silicon dioxide gate insulating film is used, the physical thickness of the silicon dioxide gate insulating film must be made thin, whereby a depletion charge existent in the polycrystal silicon gate electrode approaches the channel, mobility is reduced by the scattering of remote charge by this depletion charge. We have found that whether the carriers are electrons or holes, mobility becomes higher in the accumulation mode than in the inversion mode. A rise in mobility in the accumulation mode becomes marked particularly when the effective electric field applied to the channel portion is small. This is because the number of channel carriers is small on a low electric field side and charge is not fully screened. Therefore, this shows that the accumulation mode SOI device is resistant to a reduction in mobility caused by the scattering of remote charge. Accordingly, it has been found that the accumulation mode SOI device experiences a small reduction in mobility caused by the scattering of remote charge. When a silicon dioxide gate insulating film is used, an increase in mobility shown in FIG. 2 is small as the amount of fixed charge existent in the film is small. In contrast to this, when a high-dielectric gate insulating film is used, mobility is greatly reduced by the scattering of remote charge caused by the fixed charge existent in the film in large quantities. Therefore, it has been conceived that when a high-dielectric gate insulating film is used, a large increase in mobility can be expected from the operation of the device in the accumulation mode, which is very effective.

We have conducted simulation to clarify the mechanism of improvement of mobility in the accumulation mode in consideration of a quantum effect. FIG. 3 shows the obtained dependence on gate voltage of the distance between the surface of the substrate and the channel centroid. It is seen that the channel is formed about 1 nm more inside of the substrate in the accumulation mode than in the inversion mode. This is because a drive current is caused to run by using a large number of carriers in the accumulation mode SOI device, whereby an electric field to be applied to the channel portion can be relaxed. Due to this relaxation of an electric field, when the SOI device is operated in the accumulation mode, the distance between an interface trap existent near the surface of the substrate or fixed charge existent in the gate insulating film and the channel can be made about 1 nm larger, thereby making it possible to reduce scattering potential. Since the thickness of the gate insulating film is reduced by 0.1 nm to 0.2 nm each generation, the distance of 1 nm is equivalent to the distance between fixed charge and a channel when a gate insulating film of five or more generations ago is used and sufficiently long enough to suppress scattering by the fixed charge.

Therefore, it has been made clear that the scattering of carriers caused by an interface trap level existent at the interface with the silicon substrate or the scattering of carriers caused by the fixed charge existent in the gate insulating film can be suppressed and thereby mobility can be improved. Accordingly, when a high-dielectric gate insulating film is used in the accumulation mode SOI device, the same effect as an increase in mobility which is expected when the thickness of an interface oxide film is increased by about 1 nm can be obtained without increasing the thickness of the interface oxide film. Consequently, the accumulation mode SOI device which comprises a high-dielectric gate insulating film can recover mobility to the same level as the universal curve while its EOT is reduced. That is, the SOI device which comprises a high-dielectric gate insulating film and operates in an accumulation mode is a device which is hardly affected by the scattering of remote charge caused by the fixed charge existent in the gate insulating film, can achieve high mobility and a reduction in its EOT and can reduce a leak current by two to four digits as compared with when a silicon dioxide gate insulating film is used.

It should be noted that the accumulation mode SOI device differs from a so-called buried channel transistor. In the buried channel transistor, a PN junction is formed in the channel portion on the surface of a substrate. Therefore, the buried channel is formed at a depth of 50 to 200 nm from the surface of the substrate. As shown in FIG. 3, a channel is formed at a depth of 1 nm to 5 nm from the surface of the substrate in the accumulation mode SOI device. Therefore, the accumulation mode SOI device is a surface channel transistor and not a buried channel transistor. Structurally, the accumulation mode SOI device in which no PN junction is formed can be clearly distinguished from the buried channel transistor. In the buried channel transistor, it is difficult to control a single channel effect and therefore it is difficult to design the operation of a fine CMOS. In contrast to this, since the accumulation mode SOI device comprises a SOI substrate resistant to the single channel effect, the design of a fine CMOS is easy. Further, as a channel is formed in a very deep portion in the buried channel transistor, the capacity of the device is reduced by depletion capacity existent between the channel and the surface of the substrate, thereby reducing a drive current. In contrast to this, as the accumulation mode SOI device is a surface channel transistor, when an accumulation layer is formed, a reduction in capacity does not occur due to the existence of no depletion layer on the surface, thereby making it possible to obtain a large drive current.

The full depletion type SOI-CMOS device is a device in which when a CMOS transistor is off, a SOI layer is fully depleted. That is, when the thickness of the SOI layer is represented by t_{SOI} and the maximum thickness of the depletion layer is represented by W_{dep}, the condition t_{SOI}<W_{dep} must be satisfied to have the CMOS transistor fully depleted.

In addition, to operate a fine fully depleted SOI-CMOS device, a short channel effect must be suppressed and the SOI layer must be made thinner than the condition t_{SOI}<W_{dep}. According to the document prepared by K. Suzuki et al. [IEEE, Trans. Electron Devices, Vol. 40, p. 2326 (1993)], when the dielectric constant of silicon is represented by ∈ₛᵢ, the gate length is represented by L_{g}, and the parameter is defined by the following equation 1, the condition L_{g}/2λ>3 must be satisfied.

$$λ = \sqrt{\frac{{ϵ}_{Si} {t}_{SOI} {t}_{ox}}{2 {ϵ}_{Si}} ( 1 + \frac{{ϵ}_{ox} {t}_{SOI}}{4 {ϵ}_{Si} {t}_{ox}} )} \qquad Equation 1$$

It is understood from the above equation that t_{SOI}<40 nm must be satisfied to operate a fully depleted SOI-CMOS transistor having an oxide equivalent thickness tₒₓ of 1.5 nm and an L_{g} of 100 nm as typical values.

### BRIEF DESCRIPTION OF THE DRAWINGS

FIG. 1 is a sectional view of a semiconductor device according to a first embodiment of the present invention;

FIG. 2 shows comparison between an accumulation mode device and an inversion mode device;

FIG. 3 shows the distance between the surface of a substrate and channel centroid;

FIG. 4 is a sectional view of an SOI substrate used in the first embodiment of the present invention;

FIG. 5 is a sectional view showing a production step of the semiconductor device according to the first embodiment of the present invention;

FIG. 6 is a sectional view showing a production step of the semiconductor device according to the first embodiment of the present invention;

FIG. 7 is a sectional view showing a production step of the semiconductor device according to the first embodiment of the present invention;

FIG. 8 is a sectional view showing a production step of the semiconductor device according to the first embodiment of the present invention;

FIG. 9 is a sectional view showing a production step of the semiconductor device according to the first embodiment of the present invention;

FIG. 10 is a sectional view showing a production step of the semiconductor device according to the first embodiment of the present invention;

FIG. 11 is a sectional view showing a production step of the semiconductor device according to the first embodiment of the present invention;

FIG. 12 is a sectional view showing a production step of the semiconductor device according to the first embodiment of the present invention;

FIG. 13 is a sectional view showing a production step of the semiconductor device according to the first embodiment of the present invention;

FIG. 14 is a sectional view showing a production step of the semiconductor device according to the first embodiment of the present invention;

FIG. 15 is a sectional view showing a production step of the semiconductor device according to the first embodiment of the present invention;

FIG. 16 is a sectional view showing a production step of the semiconductor device according to the first embodiment of the present invention;

FIG. 17 is a sectional view showing a production step of the semiconductor device according to the first embodiment of the present invention;

FIG. 18 shows the effect of improving mobility according to the first embodiment of the present invention;

FIG. 19 is a sectional view showing a production step of a semiconductor device according to the second embodiment of the present invention;

FIG. 20 is a sectional view showing a production step of the semiconductor device according to the second embodiment of the present invention;

FIG. 21 is a sectional view showing a production step of the semiconductor device according to the second embodiment of the present invention;

FIG. 22 is a sectional view showing a production step of the semiconductor device according to the second embodiment of the present invention;

FIG. 23 is a sectional view showing a production step of the semiconductor device according to the second embodiment of the present invention;

FIG. 24 is a sectional view showing a production step of the semiconductor device according to the second embodiment of the present invention;

FIG. 25 is a sectional view showing a production step of the semiconductor device according to the second embodiment of the present invention; and

FIG. 26 is a sectional view showing a production step of the semiconductor device according to the second embodiment of the present invention.

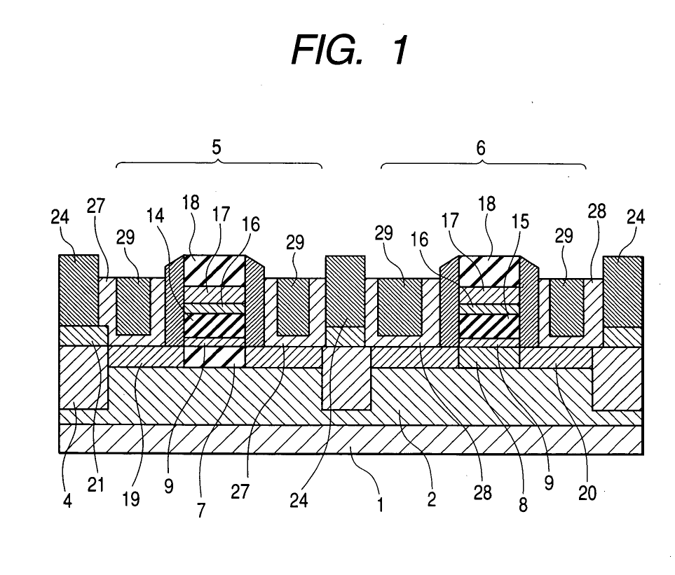

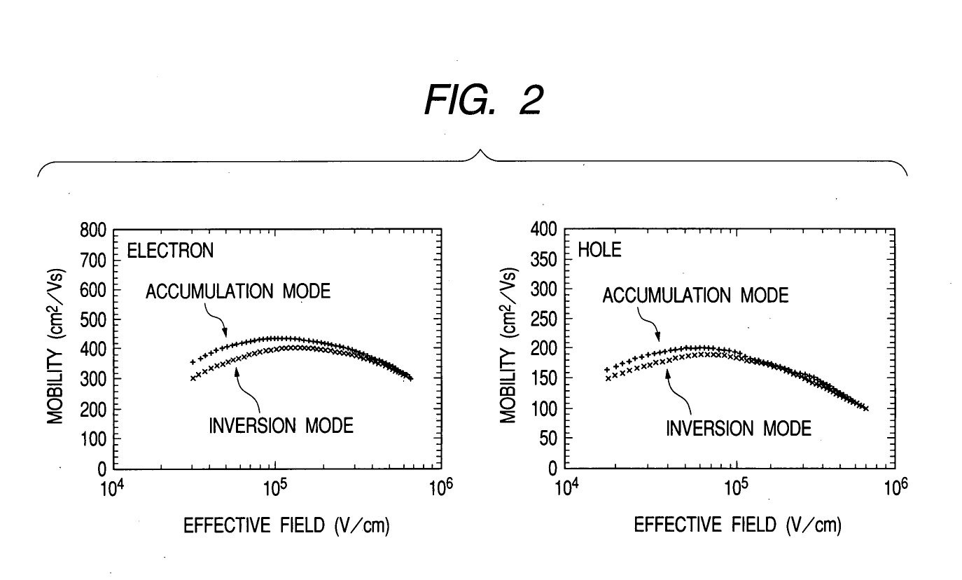

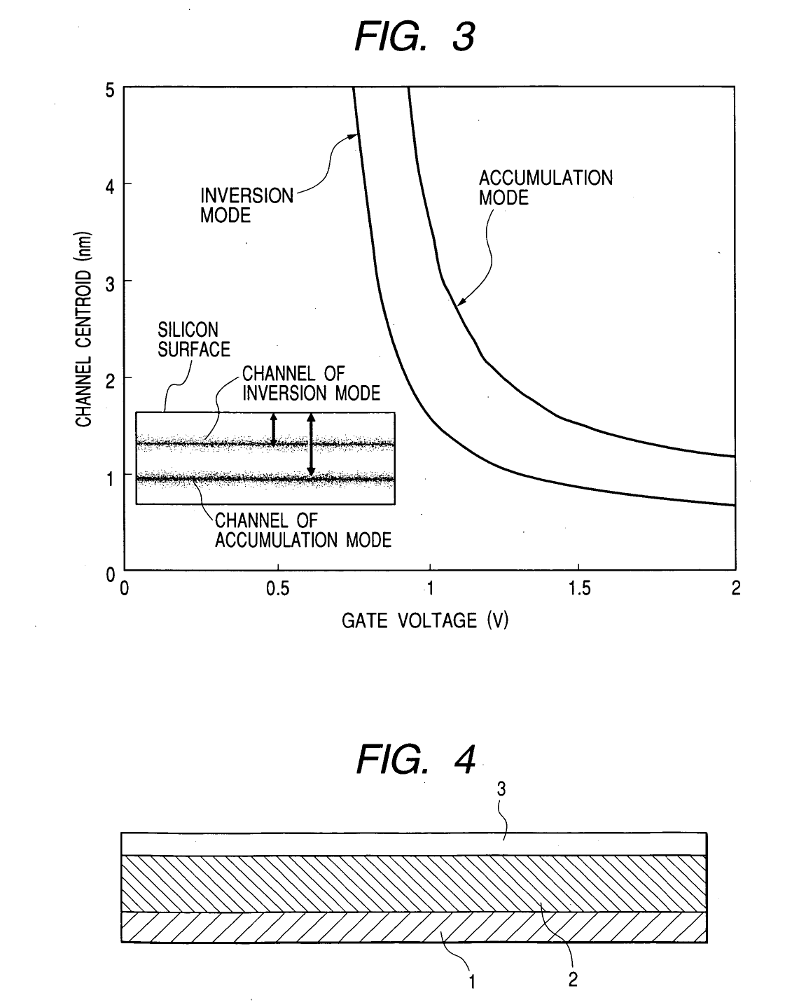

### DETAILED DESCRIPTION OF THE PREFERRED EMBODIMENTS

The following embodiments are given to further illustrate the present invention. For easy understanding, the present invention will be described with reference to the drawings and a key section is enlarged more than other sections. It is needless to say that the material, conductive type and production conditions of each portion are not limited to those described herein and various modifications may be made.

### Embodiment 1

An SOI substrate consisting of a monocrystalline silicon substrate 1, BOX layer 2 and SOI layer 3 as shown in FIG. 4 is first prepared. The SOI substrate may be produced by known methods such as a general lamination method in which two monocrystalline silicon substrates are joined together with silicon dioxide interposed therebetween or a SIMOX (Separation by IMplanted OXygen) method in which oxygen ions are injected into a Si substrate and heated at a high temperature. The SOI substrate manufactured by either one of the above methods may be used. However, since a defect may be caused by injecting oxygen ions in an SOI substrate manufactured by the SIMOX method, a substrate manufactured by the lamination method is generally preferred. The thickness of the SOI layer is preferably 10 to 40 nm because the CMOS device is fully depleted in an OFF state. When the thickness of the SOI layer in the first prepared SOI substrate is larger than 40 nm, after the SOI substrate is oxidized, silicon dioxide formed on the surface of the substrate is removed with a fluoric acid aqueous solution to make the SOI layer thin. A strained silicon layer which is a laminate of a SiGe layer and an epitaxial silicon layer may be used as the SOI layer in place of an ordinary monocrystalline silicon layer. When the strained silicon layer is used as the SOI layer, the further improvement of mobility can be expected because a rise in mobility caused by the accumulation mode operation of the present invention is added to a rise in mobility caused by use of the strained silicon layer.

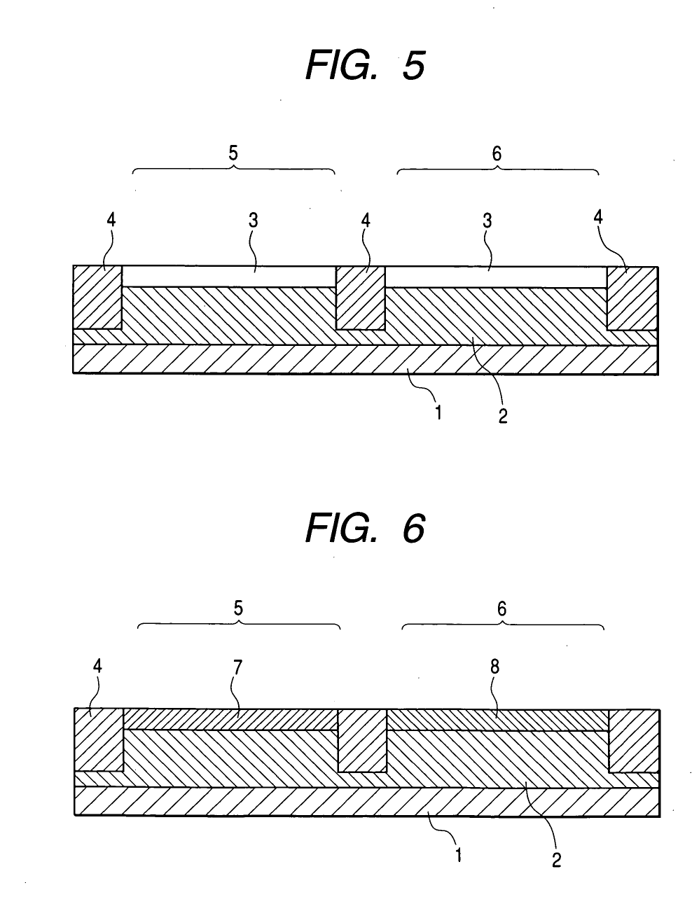

After an opening is formed in the SOI layer by dry etching using a mask made from silicon nitride, the opening is filled with silicon dioxide, and the surface is flattened by chemical mechanical polishing (CMP) to form shallow trench isolation (STI) portions 4 in order to separate devices from one another as shown in FIG. 5. In FIG. 5, an NMOS forming area 5 for forming an N type channel MOS (NMOS) and a PMOS forming area 6 for forming a P type channel MOS (PMOS) are separated from each other on the assumption of an ordinary CMOS process.

Thereafter, to adjust the threshold voltage of the CMOS device, N conductive phosphorus or arsenic ions are injected into the NMOS forming area 5 and P conductive boron ions are injected into the PMOS forming area 6. Subsequently, a heat treatment for the stretch activation of the ions is carried out to control the impurity concentration of the SOI layer to 5×10¹⁶cm⁻³, thereby forming an N⁻ type low-concentration channel area 7 and a P⁻ type low-concentration channel area 8 as shown in FIG. 6. Even when the SOI layer 3 of the SOI wafer prepared in the initial stage of FIG. 4 is of P type or N type, both the N⁻ type low-concentration channel area 7 and the P⁻ type low-concentration channel area 8 can be formed in the SOI layer without a problem by the injection of the ions and the subsequent heat treatment for activation. This is because an SOI substrate having an impurity concentration of the SOI layer of the SOI wafer prepared in the stage of FIG. 4 limitlessly close to a non-doped value can be prepared. The concentration of the impurity is about 10¹⁴cm⁻³ which is 2 digits or more lower than 5×10¹⁶cm⁻³, the concentration of an impurity added by ion injection shown in FIG. 6, and may be considered as a non-doped value. Therefore, as no PN junction is existent in the N type low-concentration channel area 7 and the P type low-concentration channel area 8, not a so-called buried channel transistor but a surface channel transistor is obtained.

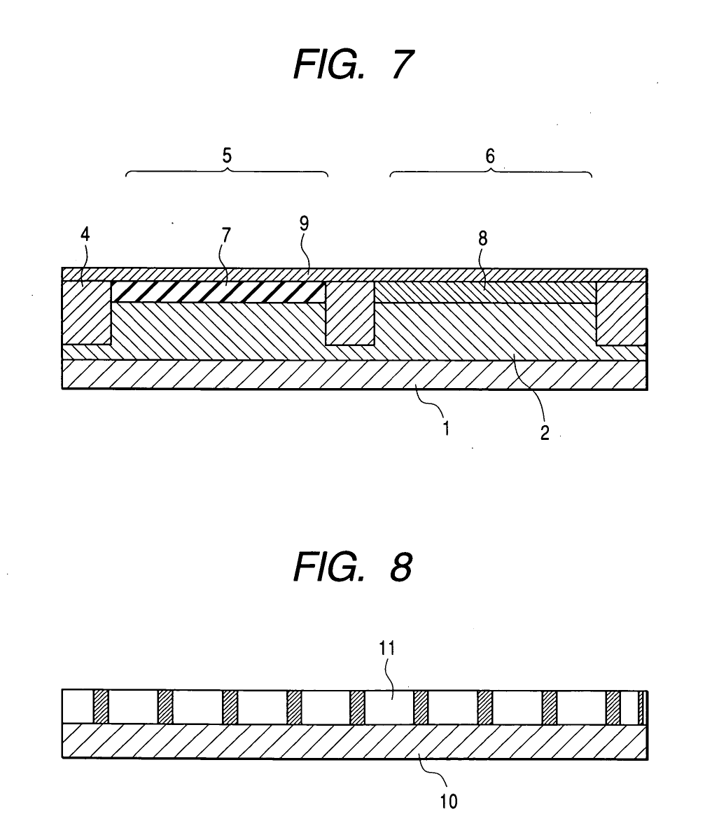

After the surface of the wafer is cleaned with a diluted fluoric acid aqueous solution, a high-dielectric gate insulating film 9 is formed as shown in FIG. 7. A silicon oxy nitride film, silicon nitride film, Al₂O₃ film, HfO₂ film, ZrO₂ film or laminated film thereof may be used as the high-dielectric gate insulating film. Accumulation mode SOI devices were manufactured by using various high-dielectric gate insulating film materials in this embodiment, and the improvement of mobility could be confirmed in all of them.

The method of forming a high-dielectric gate insulating film which could markedly improve mobility and had the smallest leak current will be disclosed hereinbelow.

A silicon oxy nitride film 10 containing a large amount of nitrogen is first formed at the interface to a physical thickness of 1.5 nm. After an Al₂O₃ film, HfO₂ film or ZrO₂ is formed to a thickness of about 1.5 nm by Atomic Layer Chemical Vapor Deposition (ALCVD), the surface is nitrided to form an Al, Hf or Zr oxy nitride film 11. Subsequently, the resulting laminate is annealed in a nitrogen atmosphere at 1,000° C. FIG. 8 is an enlarged view of the high-dielectric gate insulating film 9 which is the thus formed laminated film. The high-dielectric gate insulating film 9 tan be made as thin as 1.1 nm to 1.5 nm in terms of EOT. The leak current could be made 3 to 5 digits smaller than a silicon dioxide gate insulating film, and mobility could be made equal to that of the universal curve. Since nitrogen is added to the surface of the high-dielectric gate insulating film, a phenomenon that an impurity is diffused into the high-dielectric gate insulating film from the gate electrode, so-called “projection of an impurity”, can be prevented. In addition, when the first formed silicon oxy nitride film is made thinner, EOT can be easily further reduced.

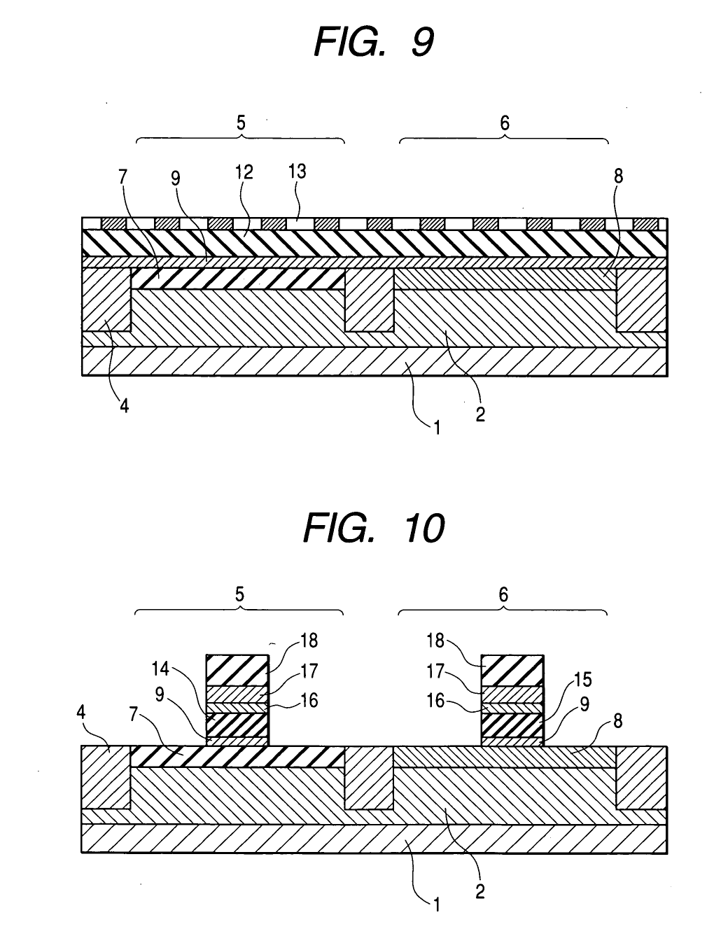

After polycrystal silicon 12 is deposited on the entire surface, a silicon dioxide film 13 is formed on the surface of the polycrystal silicon to a thickness of about 10 nm in order to protect the surface as shown in FIG. 9. Then, P conductive boron ions are injected into the NMOS forming area 5 to form P type polycrystal silicon 14 and N conductive phosphorus or arsenic ions are injected into the PMOS forming area 6 to form N type polycrystal silicon 15. Subsequently, a heat treatment is carried out in a nitrogen atmosphere at 950° C. for 30 seconds for the stretch activation of the ions to adjust the impurity concentration to about 1×10²⁰cm⁻³.

After the sacrifice oxide film 13 is removed with a fluoric acid aqueous solution, WN16 is deposited to a thickness of 5 nm as a barrier metal, W17 is deposited to a thickness of 50 nm as a metal electrode, and silicon dioxide 18 is deposited to a thickness of 10 nm as an interlayer film on the entire surface. Subsequently, dry etching is carried out using a resist mask having a desired pattern as shown in FIG. 10.

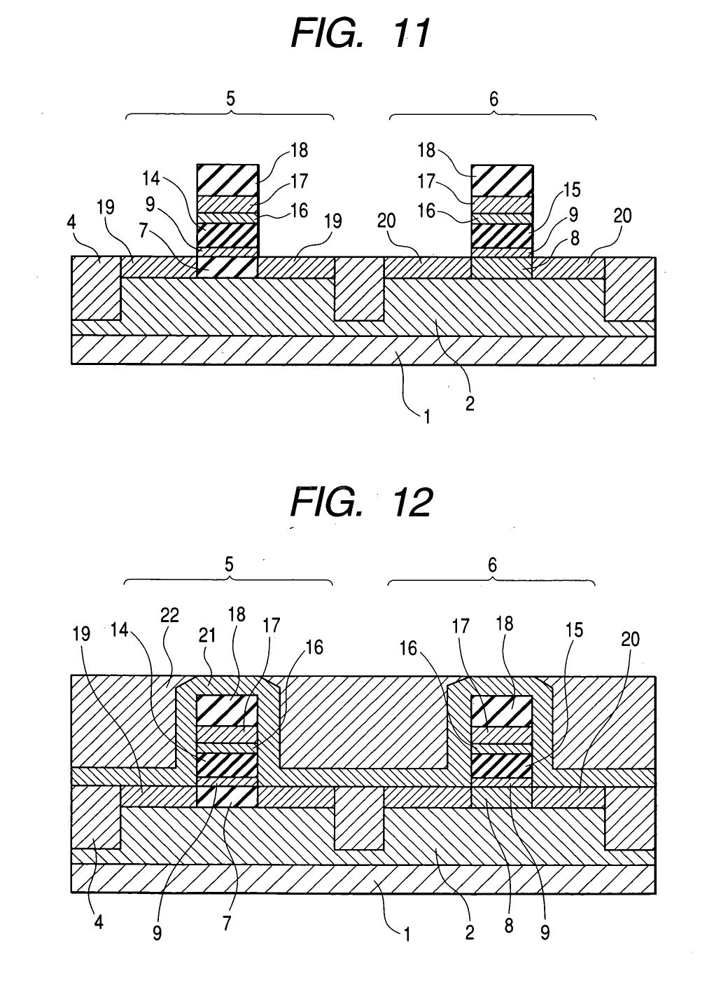

Then, N conductive phosphorus or arsenic ions are injected into the NMOS forming area 5 and P conductive boron ions are injected into the PMOS forming area 6. Subsequently, a heat treatment for the activation of the ions is carried out to form an N⁻ conductive source drain diffusion layer 19 and P⁻ conductive source drain diffusion layer 20 having an impurity concentration of about 1×10²⁰cm⁻³ as shown in FIG. 11. The conditions of the heat treatment for activation are desirably optimized according to the type of the high-dielectric gate insulating film 9. When a silicon oxy nitride film, silicon nitride film, Al₂O₃ film or laminated film thereof is used as the high-dielectric gate insulating film 9, as it can withstand a heat treatment at a high temperature, the heat treatment is carried out in a nitrogen atmosphere at 1,000° C. for 5 seconds. When an oxide film containing Hf or Zr, or oxy nitride film is used as the gate insulating film 9, if a high-temperature heat treatment is carried out, the crystallization of the gate insulating film will occur, thereby deteriorating device characteristic properties, for example, reducing mobility and increasing a leak current. Therefore, the heat treatment for activation is carried out in a nitrogen atmosphere at 850° C. for 10 seconds.

After the surfaces of the N⁺ conductive source drain diffusion layer 19 and the P⁺ conductive source drain diffusion layer 20 are silicided by a regular SALICIDE (Self-Aligned-siLICIDE) step, desired wiring maybe carried out. However, when the SOI layer 3 is thin, it is difficult to carry out the SALICIDE step. Therefore, a production process comprising no SALICIDE step will be disclosed hereinbelow.

After silicon dioxide 21 is first deposited on the entire surface to a thickness of 50 nm, polycrystal silicon 22 is deposited to a thickness of 30 nm. Subsequently, the polycrystal silicon 22 is polished by chemical mechanical polishing (CMP) until the silicon dioxide 21 is exposed to the surface as shown in FIG. 12.

Then, the polycrystal silicon 22 is dry etched to a desired pattern using a resist mask, and an opening 23 is formed above the STI portion 4 as shown in FIG. 13.

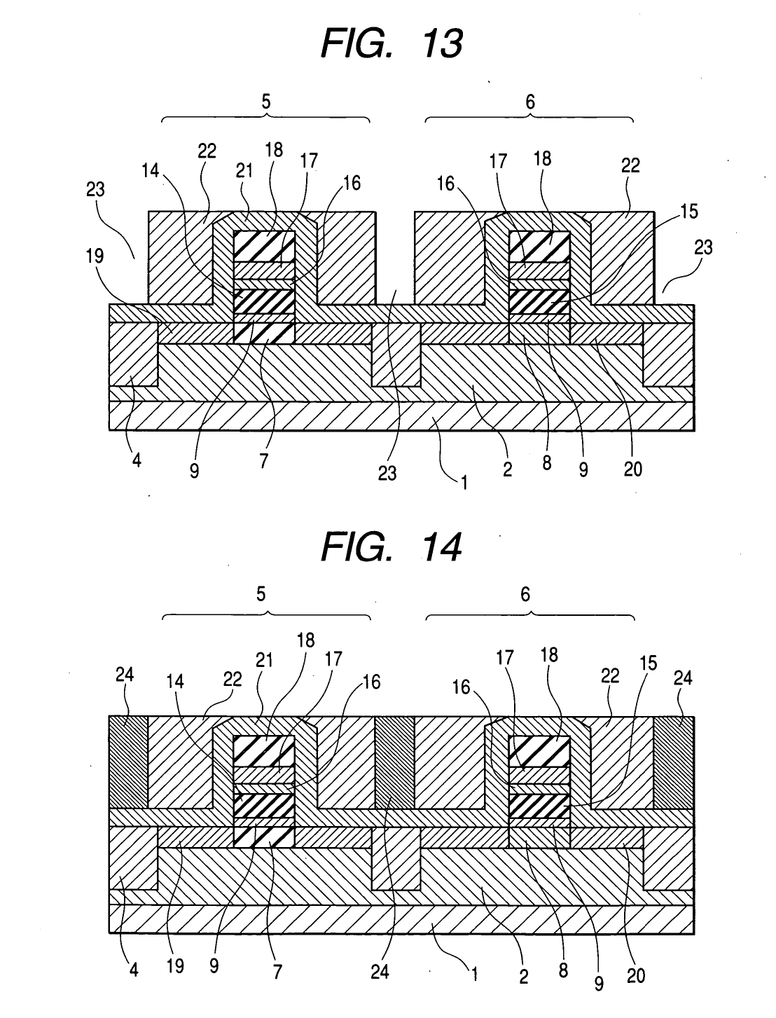

Silicon dioxide 24 is then deposited on the entire surface to fill up the opening 23. Subsequently, this silicon dioxide 24 is polished until the polycrystal silicon 22 is exposed to the surface as shown in FIG. 14.

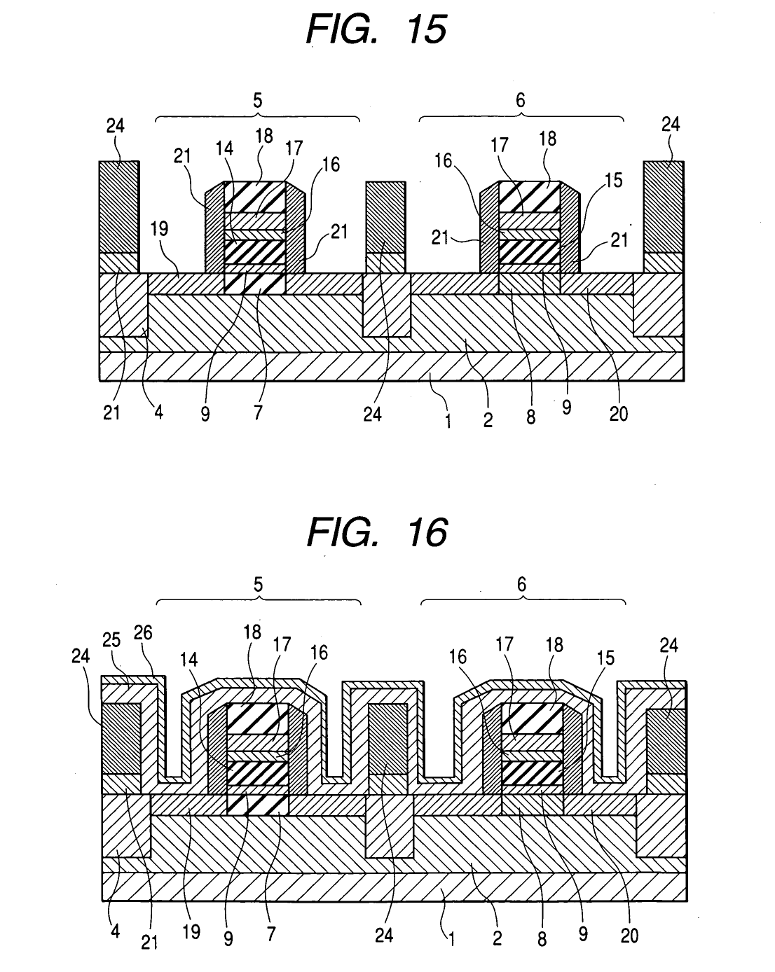

After the polycrystal silicon 22 is selectively removed by dry etching, the silicon dioxide 21 is selectively removed by 50 nm by dry etching as shown in FIG. 15.

Polycrystal silicon 25 is then deposited on the entire surface to a thickness of 30 nm. Subsequently, silicon dioxide 26 is deposited to a thickness of 10 nm as shown in FIG. 16. N conductive phosphorus or arsenic ions are injected into the NMOS forming area 5 to form an N type polycrystal silicon gate electrode 27 and P conductive boron ions are injected into the PMOS forming area 6 to form a P type polycrystal silicon gate electrode 28. A heat treatment for activation is carried out in a nitrogen atmosphere at 750° C. for 20 minutes to adjust the impurity concentrations of the N type polycrystal silicon gate electrode 27 and the P type polycrystal silicon gate electrode 28 to about 1×10²⁰cm⁻³. After the silicon dioxide 26 is removed with a fluoric acid aqueous solution, W29 is deposited on the entire surface. Subsequently, W29 is polished by CMP until the N type polycrystal silicon gate electrode 27 and the P type polycrystal silicon gate electrode 28 are exposed to the surface.

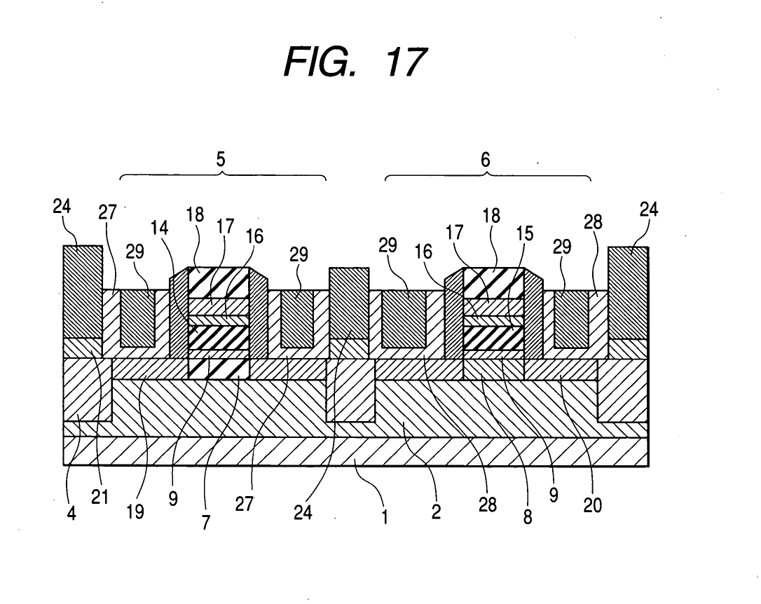

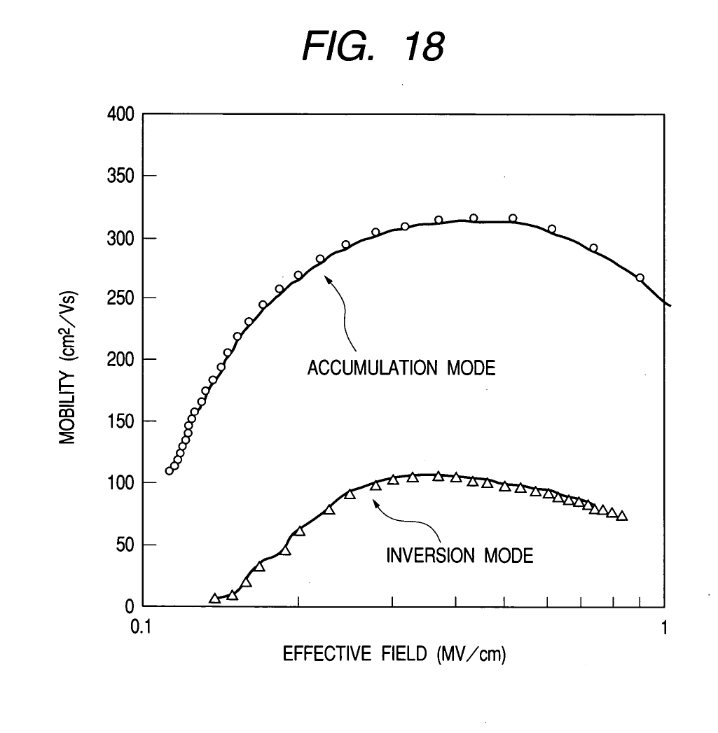

Then, W29, the N type polycrystal silicon gate electrode 27 and the P type polycrystal silicon gate electrode 28 remaining on the silicon dioxide 18 are removed by dry etching as shown in FIG. 17 to produce an accumulation mode SOI device. To integrate circuits, a desired wiring step may be carried out after this. FIG. 18 shows the effective mobility of the accumulation mode N conductive MOSFET produced in this embodiment as a function of effective electric field to be applied to the channel portion. This effective mobility is much higher than the effective mobility of a conventional inversion mode device, which can verify the effectiveness of the accumulation mode device. The mobility is increased up to about 3 times that of the inversion mode device by using the accumulation mode device. It has been verified that when a high-dielectric gate insulating film which has a serious problem, i.e., a reduction in mobility is used, it is very effective to use the high-dielectric gate insulating film for the production of an accumulation mode device. FIG. 18 shows that a laminated film consisting of a silicon oxy nitride film 10 and an Al oxy nitride film 11 disclosed in this embodiment is used as the high-dielectric gate insulating film 9. It has also been confirmed that when a halfnium oxy nitride film is used as a high-dielectric gate insulating film, mobility is increased up to about 2 times that of the inversion mode device. When a laminated film consisting of a silicon oxy nitride film 10 and an Al oxy nitride film 11 is used for a P conductive channel, mobility is increased up to about 2.5 times that of the inversion mode device and when a halfnium oxy nitride film is used, mobility is increased up to about 2.3 times that of the inversion mode device. It has also been confirmed that the leak current can be made about 10% smaller when the accumulation mode device is used than when the inversion mode device is used due to an effect obtained by forming an accumulation layer away from the interface. Therefore, it has been verified that when the high-dielectric gate insulating film is used, mobility can be improved by combining a fully depleted SOI device which operates in an accumulation mode with the film.

### Embodiment 2

In this embodiment, a thermal load on the high-dielectric gate insulating film 9 is reduced by producing an accumulation mode SOI-CMOS using a dummy gate process to achieve high mobility.

After device separation is first carried out on the SOI substrate by STI in the same step as in the above Embodiment 1, ion injection for adjusting threshold voltage and a heat treatment for activation are carried out as shown in FIG. 6.

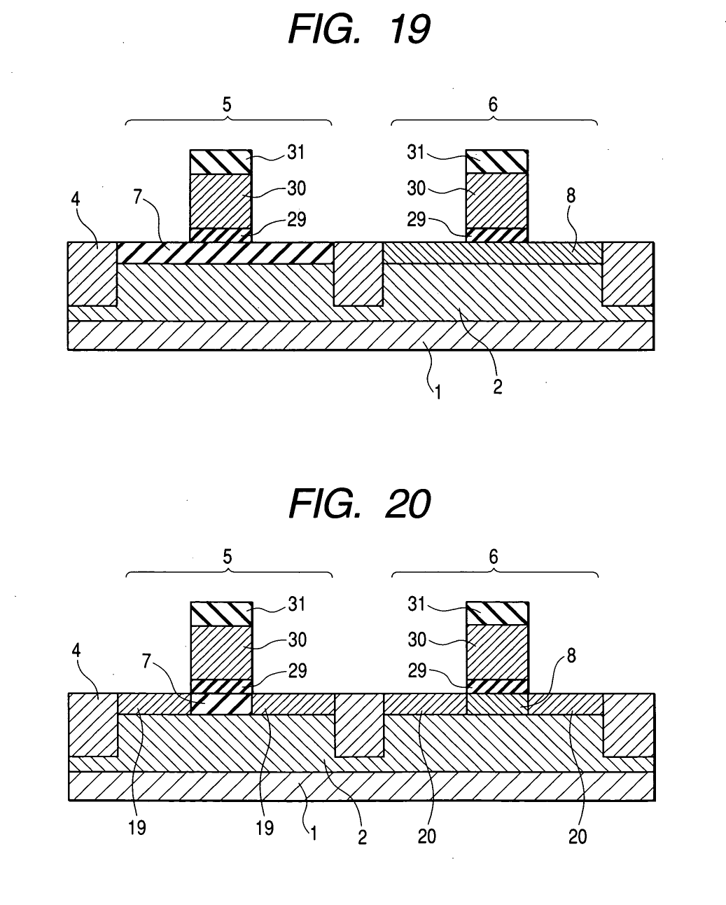

A sacrifice oxide film 29 for protecting the surface is formed to a thickness of 10 nm, polycrystal silicon 30 is deposited to a thickness of 150 nm as a dummy gate, and silicon nitride 31 is deposited to a thickness of 50 nm. Subsequently, dry etching is carried out using a resist mask to obtain a desired pattern as shown in FIG. 19.

Thereafter, N conductive phosphorus or arsenic ions are injected into the NMOS forming area 5 and P conductive boron ions are injected into the PMOS forming area 6. In order to activate the injected ions, a heat treatment is carried out in a nitrogen atmosphere at 1,000° C. for 5 seconds to form an N⁺ conductive source drain diffusion layer 19 and a P⁺ conductive source drain diffusion layer 20 having an impurity concentration of about 1×10²⁰cm⁻³ as shown in FIG. 20. Since the heat treatment for activation is carried out before the formation of the high-dielectric gate insulating film 9, it can be carried out at a high temperature in a short period of time. Therefore, the impurity can be activated while the impurity profiles of the N⁺ conductive source drain diffusion layer 19 and the P⁺ conductive source drain diffusion layer 20 are prevented from spreading to the N⁻ type low-concentration channel area 7 and to the P⁻ type low-concentration channel area 8, respectively. Therefore, there can be provided a process best suited for the production of an accumulation mode SOI device having a small channel length while a heat load on the high-dielectric gate insulating film 9 is reduced.

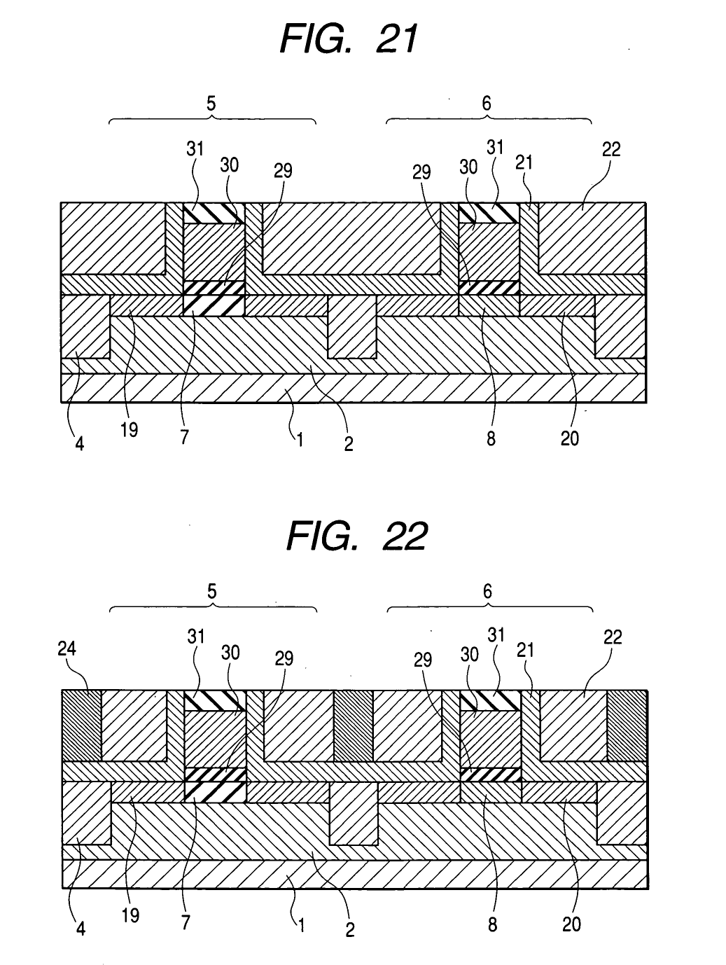

After silicon dioxide 21 is deposited on the entire surface to a thickness of 50 nm, polycrystal silicon 22 is deposited to a thickness of 30 nm. Subsequently, they are polished by chemical mechanical polishing (CMP) until the silicon nitride 31 is exposed to the surface as shown in FIG. 21.

The polycrystal silicon 22 is then dry etched to a desired pattern using a resist mask in the same manner as in Embodiment 1, and an opening 23 is formed above the STI portion 4. Thereafter, silicon dioxide 24 is deposited on the entire surface to fill up the opening 23. Then, the silicon dioxide 24 is polished by CMP until the polycrystal silicon 22 is exposed to the surface as shown in FIG. 22.

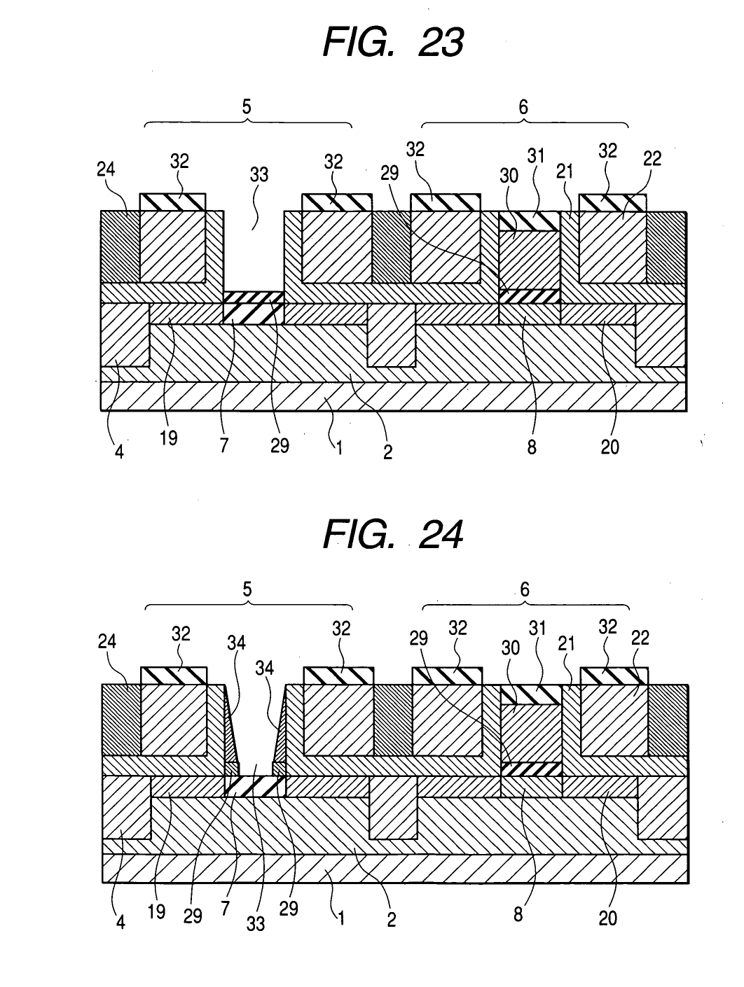

The surface of polycrystal silicon 30 is oxidized to form silicon dioxide 32 to a thickness of about 20 nm. After the NMOS forming area 5 is wet etched with a phosphate solution heated at 180° C. using a resist mask to selectively remove silicon nitride 31, the polycrystal silicon 30 is selectively removed by wet etching with fluoronitric acid to form an opening 33 as shown in FIG. 23.

After silicon nitride 34 is deposited on the entire surface, the silicon nitride 34 is dry etched so that it is left only on the side wall of the opening 33 in order to form a side wall. Subsequently, the sacrifice oxide film 29 damaged by the above dry etching is removed by wet etching. After the top surface of the N⁻ type low-concentration channel area 7 is oxidized to form a silicon dioxide film (not shown), the silicon dioxide film is removed to clean the top surface of the N⁻ type low-concentration channel area 7 as shown in FIG. 24.

A high-dielectric gate insulating film 9 is then formed. When the process step of this embodiment is used, as the heat treatment for the activation of the injected ions is over before the step of forming the high-dielectric gate insulating film 9, a heat load on the high-dielectric gate insulating film 9 can be reduced. Therefore, the crystallization of the high-dielectric gate insulating film can be prevented, and high mobility and a low leak current can be realized at the same time. A laminated film is used as the high-dielectric gate insulating film. A 0.5 nm-thick super thin oxide film 35 is first formed at the interface with the opening 33. An HfO₂ film or ZrO₂ film 36 is then formed to a thickness of about 2.0 nm by ALCVD and annealed in a reduced oxygen atmosphere at 1,000° C.

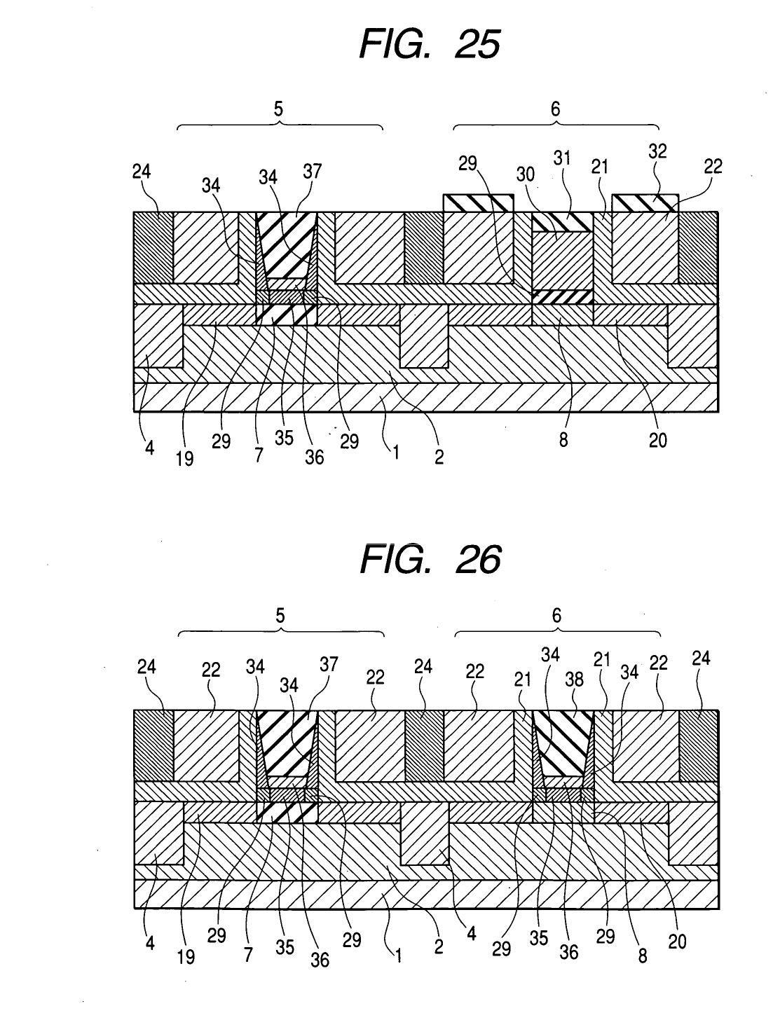

Subsequently, a gate electrode is formed. To turn off (normally off) the NMOSFET-of the accumulation mode SOI device of the present invention while gate voltage is not applied, a material having a work function close to the valence band of silicon is desirably used as a gate electrode material. In this embodiment, a TiN film 37 is deposited. Subsequently, the silicon dioxide 32 is removed as shown in FIG. 25. Then, the same step as that for the NMOS forming area 5 is carried out on the PMOS forming area 6. That is, the silicon nitride 31 and the polycrystal silicon 30 are selectively removed from the PMOS formed area 6 to form an opening, a side wall is formed from silicon nitride 34, the sacrifice oxide film 29 is removed, the surface of the P⁻ type low-concentration channel area 8 is cleaned, and a high-dielectric gate insulating film 9 which is a laminated film consisting of a super thin oxide film 35 and an HfO₂ film or ZrO₂ film 36 is formed. Thereafter, to normally turn off PMOSFET of the accumulation mode SOI device, a material having a work function close to the conduction band of silicon is used as a gate electrode material. In this embodiment, a TaSiN film 38 is used as the gate electrode. Subsequently, the silicon dioxide 32 is removed as shown in FIG. 26. To integrate circuits, a desired wiring step may be carried out after this.

It has been confirmed that the mobility of the accumulation mode SOI device comprising a high-dielectric gate insulating film produced according to this embodiment is almost the same as mobility obtained when a conventional silicon dioxide gate insulating film is used. That is, the accumulation mode SOI device of this embodiment hardly sees a reduction in mobility caused by the fixed charge existent in the high-dielectric gate insulating film. It has also been confirmed that the leak current can be made about 3 to 4 digits smaller than a device comprising a conventional silicon dioxide gate insulating film, and the above device is power-saving. It has further been confirmed that the accumulation mode SOI device of the present invention shows excellent operation even when the gate length is 20 nm and is extremely resistant to a single channel effect.

In this embodiment, two areas, that is, the NMOS forming area 5 and the PMOS forming area 6 are shown. A larger number of areas may be easily formed. In this case, the thickness and material of the high-dielectric gate insulating film formed in each area can be selected independently. Thereby, the high-dielectric gate insulating films which differ in thickness can be integrated on a single chip, thereby making it possible to significantly increase the degree of circuit design freedom.

According to the present invention, in an accumulation mode SOI device having a high-dielectric gate insulating film, a leak current running through a gate electrode can be made about 3 to 4 digits smaller than when conventional silicon dioxide is used in a gate insulating film while its mobility is maintained at the same level as that of a SOI device having a silicon dioxide gate insulating film. According to the present invention, as a channel is formed several nm away from the interface with the silicon substrate by making effective use of a quantum effect, even when a large amount of fixed charge is existent in the high-dielectric gate insulating film, an accumulation mode SOI device having the high-dielectric gate insulating film hardly sees a reduction in mobility. Therefore, when an integrated circuit is manufactured using the accumulation mode SOI device comprising the high-dielectric gate insulating film of the present invention, high-speed operation and low power consumption can be obtained at the same time.

What is claimed is:

1. A semiconductor device comprising:
a silicon on insulator (SOI) substrate having an insulating layer and a monocrystalline silicon layer formed on a base substrate;
a source diffusion portion and a drain diffusion portion both formed of a first conductive type and formed from said monocrystalline silicon layer on the surface layer of the SOI substrate;
a channel portion also formed from the monocrystalline layer and also of said first conductive type having one end adjacent to the source diffusion portion of said first conductive type and the other end adjacent to the drain diffusion portion of said first conductive type; and
a gate insulating film formed on the channel portion.

2. A semiconductor device comprising:
a SOI substrate having a surface monocrystalline silicon layer and an insulating layer formed on a base substrate;
a source diffusion portion and a drain diffusion potion both having a first conductive type formed in the surface monocrystalline silicon layer of the SOI substrate;
a channel portion also formed of said first conductive type and having one end adjacent to the source diffusion portion and the other end adjacent to the drain diffusion portion and
a gate insulating film formed on the channel portion, wherein the gate insulating film is a laminated film comprising an insulating film formed on the channel portion and a metal oxide film having a higher dielectric constant than the insulating film.

3. The semiconductor device according to claim 1, wherein the channel portion is fully depleted.

4. The semiconductor device according to claim 1, wherein no junction between the first conductive type and a second conductive type opposite to the first conductive type is formed in the monocrystalline silicon layer.

5. The semiconductor device according to claim 1, wherein the SOI substrate is a laminated substrate consisting of a first monocrystalline semiconductor layer formed on the base substrate through an insulating film and a second monocrystalline semiconductor layer formed on the first monocrystalline semiconductor layer, wherein a first lattice constant of the first monocrystalline semiconductor and a second lattice constant of the second monocrystalline semiconductor differ from each other to form a strained silicon portion in the channel portion.

6. The semiconductor device according to claim 1, wherein the concentration of a channel impurity forming the channel portion is lower than the concentration of a source/drain impurity forming the source or drain portions.

7. The semiconductor device according to claim 1, wherein the thickness of the monocrystalline silicon layer is 4 nm or less.

8. The semiconductor device according to claim 1, wherein the gate insulating film contains a silicon oxy nitride film or silicon nitride film.

9. The semiconductor device according to claim 1, wherein the gate insulating film contains a metal oxide or metal oxy nitride.

10. The semiconductor device according to claim 1, wherein the gate insulating film contains an oxide of a metal material selected from the group consisting of aluminum, hafnium and zirconium, an insulating film containing at least one of the oxides of these metal materials, an oxy nitride film of any one of the metal materials, a silicate film, or a laminated film thereof.

11. A semiconductor device comprising:
a SOI substrate having an insulating layer and a surface monocrystalline silicon layer formed on a base substrate;
at least one separation area made from an insulating material formed in the SOI substrate;
a first area in which a source diffusion portion and a drain diffusion portion both having a first conductive type are formed in the surface monocrystalline silicon layer of the SOI substrate bounded by the separation area;
a second area which is adjacent to the first area and adjacent to the separation area and in which opposite type source and drain diffusion portions having an opposite conductive type to the first conductive type are formed, wherein
a gate insulating film formed on a channel portion having one end adjacent to the source diffusion portion and the other end adjacent to the drain diffusion portion in the first and second areas,
the gate insulating film comprising a laminated film of an insulating film formed on the channel portion and a metal oxide film having a higher dielectric constant than the insulating film, and
wherein the channel portion of the first area has the first conductive type and the channel portion of the second area has the second conductive type.

12. The semiconductor device according to claim 2, wherein the channel portion is fully depleted.

13. The semiconductor device according to claim 2, wherein no junction between the first conductive type and a second conductive type opposite to the first conductive type is formed in the monocrystalline silicon layer.

14. The semiconductor device according to claim 2, wherein the SOI substrate is a laminated substrate consisting of a first monocrystalline semiconductor layer formed on the substrate through an insulating film and a second monocrystalline semiconductor layer formed on the first monocrystalline semiconductor layer, wherein a first lattice constant of the first monocrystalline semiconductor and a second lattice constant of the second monocrystalline semiconductor differ from each other to form a strained silicon layer in the channel portion.

15. The semiconductor device according to claim 2, wherein the concentration of an impurity forming the channel portion is lower than the concentration of an impurity forming the source or drain portions.

16. The semiconductor device according to claim 2, wherein the thickness of the monocrystalline silicon layer is 4 nm or less.

17. The semiconductor device according to claim 2, wherein the gate insulating film contains a silicon oxy nitride film or silicon nitride film.

18. The semiconductor device according to claim 2, wherein the gate insulating film contains a metal oxide or metal oxy nitride.

19. The semiconductor device according to claim 2, wherein the gate insulating film contains an oxide of a metal material selected from the group consisting of aluminum, hafnium and zirconium, an insulating film containing at least one of the oxides of said metal materials, an oxy nitride film of any one of said metal materials, a silicate film, or a laminated film thereof.
